(19) United States
(12) Patent Application Publication
(10) Pub. No.: US 2012/0132274 A1
(43) Pub. Date: May 31, 2012

(54) PROCESS FOR THE PRODUCTION OF A STRUCTURED METALLIC COATING

(75) Inventors: Frank Kleine Jaeger, Bad Duerkheim (DE); Stephan Hermes, Neustadt (DE)

(73) Assignee: BASF SE, Ludwigshafen (DE)

(21) Appl. No.: 13/380,259

(22) PCT Filed: Jun. 18, 2010
(86) PCT No.: PCT/EP2010/058612

§ 371 Date: Feb. 16, 2012

(30) Foreign Application Priority Data
Jun. 22, 2009 (EP) 09163346.1

(51) Int. Cl. H01L 31/0216; H01L 31/18; H01L 21/3205

(52) U.S. Cl. 136/256; 438/677; 438/98; 257/E21.294; 257/E31.119

(57) ABSTRACT

The invention relates to a process for the production of a structured electrically conductive coating on a substrate, in which first a monolayer or oligolayer of a surface-hydrophobizing substance is applied to a surface of the substrate and then a substance comprising electrically conductive particles is applied to the substrate according to a predetermined pattern. The invention furthermore relates to a use of the process for the production of solar cells or circuit boards and to an electronic component comprising a substrate to which a structured electrically conductive surface is applied, a monolayer or oligolayer of a surface-hydrophobizing material being applied to the substrate and the structured electrically conductive surface being applied to the monolayer or oligolayer.

The invention relates to a process for the production of a structured metallic coating on a substrate. The invention furthermore relates to a use of the process for the production of solar cells or circuit boards and an electronic component which comprises a substrate to which a structured metallic surface is applied.

Structured metallic coatings on a substrate are produced, for example, by printing processes. For this purpose, a metallic particle-containing ink is applied to the substrate, for example by an inkjet printing process or a laser printing process. A corresponding process in which ink drops are thrown from a carrier coated with an ink onto a substrate to be printed on is disclosed, for example, in U.S. Pat. No. 6,241,344. For transferring the ink, energy is introduced into the ink on the carrier at the position at which the substrate is to be printed on. As a result of this, a part of the ink vaporizes so that it becomes detached from the carrier. The ink drop detached in this manner is thrown onto the substrate by the pressure of the vaporizing ink. By specific introduction of energy, the ink can be transferred to the substrate in this way according to a pattern to be printed. The necessary energy for transferring the ink is introduced, for example, by a laser. The carrier on which the ink is applied is, for example, a revolving belt to which ink is applied with the aid of an application apparatus before the printing area. The laser is present in the interior of the revolving belt, so that the laser acts on the carrier on the side facing away from the ink.

However, a disadvantage of such processes is in general that the print quality depends to a great extent on the homogeneity of the conditions involved in the process. Thus, even very small local differences can lead to a qualitative deterioration in the printing result directly at the point of introduction of the energy. Such differences are, for example, differences in the thickness of the ink coat and, for example, also the electrostatic state of the substrate to be printed on. Thus, for example, a customary polymer or paper surface has a completely disordered static surface charge, which is also very inhomogeneous in its voltage potential, owing to various rolling processes. The printed image resulting therefrom has a very great tendency toward inexact edges and borders, which is caused mainly by undefined spraying and misting of the ink. A further cause of inexact edges and borders is also nonuniform leveling of the ink on the substrate to be printed on.

To ensure that water drops or oil drops do not wet a surface but retain substantially a spherical form, it is known to apply a silane-comprising layer to a surface. Such a layer is described, for example, in EP-A 0 497 189. However, a disadvantage of the coating of the process described here is that the surface to be coated requires active hydrogen, for example in the form of hydroxyl groups, imino groups or amino groups on the surface, on the surface. Moreover, the layer is used for repelling water or oil. The application of a structured layer to the silane-comprising surface is not envisaged.

It is an object of the present invention to provide a process for the production of a structured metallic coating on a substrate, in which a structured metallic layer having clearly defined exact edges and borders is produced.

The object is achieved by a process for the production of a structured metallic coating on a substrate, which comprises the following steps:
(a) application of a monolayer or oligolayer of a surface-hydrophobizing substance to a surface of the substrate,
(b) imprinting of a substance comprising electrically conductive particles according to a predetermined pattern on the substrate.

Preferably, a monolayer of a surface-hydrophobizing substance is applied to the surface of the substrate. However, layers comprising 2 or 3 plies can also form in isolated cases.

By applying the monolayer or oligolayer of a surface-hydrophobizing substance to the surface of the substrate, it is ensured that the substance applied to the substrate and comprising electrically conductive particles runs to a lesser extent or optimally does not run but retains its structure. By applying only one monolayer or oligolayer, it is furthermore ensured that, particularly in the case of a substrate comprising a semiconductor material, any influence of the surface-hydrophobizing substance on the properties of the structured metallic coating and of the semiconductor substrate can be minimized so that the properties of a product to be produced are not adversely affected. The more exact edge contour possible in this manner furthermore has the advantage that a crisp, highly resolved printed image having structures which are substantially smaller than 100 μm can be printed. Such a highly resolved printed image having structures below 100 μm is advantageous, for example, for the production of solar cells. For the production of solar cells, usually silver pastes are applied by screen printing techniques on a silicon nitride-coated or passivated surface of a wafer. However, structures which are substantially smaller than 100 μm cannot be reliably printed by screen printing processes. Alternatively, it is known, for example, from U.S. Pat. No. 5,021,808, to print by means of a laser-absorbing ink, the ink being applied to a transparent continuous film and a laser being focused from the back onto the front of the film so that the laser-absorbing film present there is heated to such an extent that parts of the solvent of the ink evaporate abruptly. In this way, an ink drop is transferred to the substrate, for example the solar wafer. However, only inks whose viscosities are substantially lower than those of comparable screen printing pastes are suitable for printing. After the transfer of the inks to textured and silicon nitride-coated wafers, it is however observed that the ink runs on the surface. By coating according to the invention with a surface-hydrophobizing substance on the already silicon nitride-coated or passivated wafers, running is reduced or ideally even suppressed. The printed image produced therefore has even crisper edges and a finer printed image is possible.

In addition to silicon nitride-coated wafers, it is also possible to use wafers coated with aluminum oxide (Al₂O₃) or with silicon carbide (SiC).

In the case of solar cells, the printed image usually has two to three broader strips to which tapes for connecting a plurality of cells are subsequently soldered. Furthermore, the cells have a very thin grid having good electrical conductivity. The requirements with regard to this grid are very high. It must be highly conductive but must hinder the incidence of light only as little as possible. For this reason, the individual tracks of the grid must be applied as narrowly as possible and be of maximum thickness.

In order to obtain conductive grids, an ink which comprises electrically conductive particles in a solvent is used.

The electrically conductive particles which are applied for producing the structured metallic coating to the substrate preferably comprise silver, copper, iron, tin, nickel or mixtures or alloys of these metals. Very particularly preferably, particularly in the production of solar cells, electrically conductive particles which comprise silver and/or optionally nickel are used. The particles used may assume any desired shape known to the person skilled in the art. It is also possible to use two or more different particles, it being possible for the particles to differ in their size, shape or material. Usually, particles of different shape, for example spherical particles and lamellar particles are used. The particles may also differ in particular in their size.

The size of the particles is chosen in general so that the dimensions of the structure to be printed are substantially greater than the maximum dimensions of the particles. Preferably, particles having a size of not more than 10 μm are used. In particular, it is also possible to use nanoparticles as particles in the substance to be applied to the substrate.

Suitable solvents in which the particles are dispersed are any desired solvents known to the person skilled in the art. Suitable solvents are, for example water or organic solvents.

Matrix materials usually present in the substance comprising the electrically conductive particles are, for example, ABS (acrylonitrile-butadiene-styrene); ASA (acrylonitrile-styrene-acrylate); acrylated acrylates; alkyd resins; alkyl-vinyl acetates; alkylene-vinyl acetate copolymers, in particular methylene-vinyl acetate, ethylene-vinyl acetate, butylene-vinyl acetate; alkylene-vinyl chloride copolymers; amino resins; aldehyde and ketone resins; cellulose and cellulose derivatives, in particular hydroxyalkylcellulose, cellulose esters, such as cellulose acetates, propionates, butyrates, carboxyalkylcelluloses, cellulose nitrate; epoxy acrylates; epoxy resins; modified epoxy resins, for example bifunctional or polyfunctional bisphenol A or bisphenol F resins, polyfunctional epoxy novolak resins, brominated epoxy resins, cycloaliphatic epoxy resins; aliphatic epoxy resins, glycidyl ethers, vinyl ethers, ethylene-acrylic acid copolymers; hydrocarbon resins; MABS (transparent ABS comprising acrylate units); melamine resins, maleic anhydride copolymers; methacrylates; natural rubber; synthetic rubber; chlorine rubber; natural resins; rosins; shellac; phenol resins; phenoxy resins, polyesters; polyester resins, such as phenyl ester resins; polysulfones; polyethersulfones; polyamides; polyimides; polyanilines; polypyrroles; polybutylene terephthalate (PBT); polycarbonate (for example Makrolon® from Bayer AG); polyester acrylates; polyether acrylates; polyethylene; polyethylene thiophenes; polyethylene naphthalates; polyethylene terephthalate (PET); polyethylene terephthalate-glycol (PETG); polypropylene; polymethyl methacrylate (PMMA); polyphenylene oxide (PPO); polystyrenes (PS), polytetrafluoroethylene (PTFE); polytetrahydrofuran; polyethers (for example polyethylene glycol, polypropylene glycol), polyvinyl compounds, in particular polyvinyl chloride (PVC), PVC copolymers, PVdC, polyvinyl acetate and the copolymers thereof, optionally partly hydrolyzed polyvinyl alcohol, polyvinyl acetals, polyvinyl acetates, polyvinylpyrrolidone, polyvinyl ethers, polyvinyl acrylates and methacrylates in solution and as a dispersion and copolymers thereof, polyacrylates and polystyrene copolymers, for example polystyrene-maleic anhydride copolymers; polystyrene (toughened or untoughened); polyurethanes, uncrosslinked or crosslinked with isocyanates; polyurethane acrylates; styrene-acrylate copolymers; styrene-butadiene block copolymers (for example Styroflex® or Styrolux® from BASF AG, K-Resin™ from CPC); proteins, for example casein; styrene-isoprene block copolymers; triazine resins, bismaleimide-triazine resins (BT), cyanate ester resin (CE), allylated polyphenylene ethers (APPE). Furthermore, mixtures of two or more polymers may form the matrix material.

The matrix material may furthermore comprise fillers. Suitable fillers are, for example, glass frits or organometallic compounds.

Suitable solvents are, for example, aliphatic and aromatic hydrocarbons (for example n-octane, cyclohexane, toluene, xylene), alcohols (for example methanol, ethanol, 1-propanol, 2-propanol, 1-butanol, 2-butanol, amyl alcohol), polyhydric alcohols, such as glycerol, ethylene glycol, propylene glycol, neopentyl glycol, alkyl esters (for example methyl acetate, ethyl acetate, propyl acetate, butyl acetate, isobutyl acetate, isopropyl acetate, 3-methylbutanol), alkoxy alcohols (for example methoxypropanol, methoxybutanol, ethoxypropanol), alkylbenzenes (for example ethylbenzene, isopropylbenzene), butyl glycol, butyl diglycol, alkyl glycol acetates (for example butyl glycol acetate, butyl diglycol acetate), dimethylformamide (DMF), diacetone alcohol, diglycol dialkyl ether, diglycol monoalkyl ether, dipropylene glycol dialkyl ether, dipropylene glycol monoalkyl ether, diglycol alkyl ether acetates, dipropylene glycol alkyl ether acetates, dioxane, dipropylene glycol and dipropylene ether, diethylene glycol and diethylene ether, DBE (dibasic esters), ethers (for example diethyl ether, tetrahydrofuran), ethylene chloride, ethylene glycol, ethylene glycol acetate, ethylene glycol dimethyl ester, cresol, lactones (for example butyrolactone), ketones (for example acetone, 2-butanone, cyclohexanone, methyl ethyl ketone (MEK), methyl isobutyl ketone (MIBK)), methyl diglycol, methylene chloride, methylene glycol, methyl glycol acetate, methylphenol (ortho-, meta-, para-cresol), pyrrolidones (for example N-methyl-2-pyrrolidone), propylene glycol, propylene carbonate, carbon tetrachloride, toluene, trimethylolpropane (TMP), aromatic hydrocarbons and mixtures, aliphatic hydrocarbons and mixtures, alcoholic monoterpenes (such as, for example, terpineol), 2,2,4-trimethyl-1,3-pentanediol monoisobutyrate (Texanol®), water and mixtures of two or more of these solvents.

By applying the monolayer of the surface-hydrophobizing substance, running of the substance comprising the electrically conductive particles is avoided or limited. The application of the monolayer of the surface-hydrophobizing substance is effected by any desired method known to a person skilled in the art. Usually, the surface-hydrophobizing substance is applied to the surface of the substrate by vapor deposition, spraying on or immersion. If the surface-hydrophobizing substance is applied to the substrate by vapor deposition, the vapor deposition is preferably effected under reduced pressure. The pressure range for the vapor deposition is used in the range from atmospheric pressure to 10⁻⁶ mbar (abs), preferably in the range from 100 mbar (abs) to 10⁻⁶ mbar (abs). The vapor deposition is usually effected at a temperature in the range from 10 to 500° C., preferably in the range from 10 to 100° C., in particular at room temperature.

If the application of the surface-hydrophobizing substance is effected by spraying on, a solution which comprises the surface-hydrophobizing substance is usually applied to the substrate by spraying immersion and then dried. On drying, a self-organizing monolayer of the surface-hydrophobizing substance is deposited on the substrate. In emerging methods in which the substrate to be coated is immersed in a solution comprising the surface-hydrophobizing substance or the substrate is placed in a highly dilute solution of the surface-hydrophobizing substance, a self-organizing monolayer of the surface-hydrophobizing substance is deposited on the surface of the substrate. In order to avoid washing off silanes which have reacted with the surface, the substrate is generally washed or cleaned with a solvent after the spraying or immersion. Suitable surface-hydrophobizing substances are preferably compounds (S) which have at least one, preferably exactly one, at least monoalkoxylated, for example mono- to trialkoxylated, preferably exactly trialkoxylated silyl group and at least one, preferably exactly one, group R which has hydrophobic properties.

The compounds (S) are preferably those of the formula

Xₙ—Si—R₍₄₋ₙ₎

in which

X is alkoxy, carboxylic acid, for example acetate, halogen, for example chlorine, amines or hydroxyl, n is an integer from 1 to 3, preferably 3.

Preferably, X is ethoxy, methoxy or chlorine, it being possible, when n is greater than 1, for each radical X, also independently of one another, to be one of said groups, it being possible for the individual radicals X to differ from one another.

R is an organic, hydrophobic radical comprising 1 to 20 carbon atoms, it being possible for the radicals R to differ in the case of n<3.

Preferably, R is C₁- to C₂₀-alkyl, C₆- to C₁₈-aryl or C₅- to C₁₂-cycloalkyl.

Examples of C₁- to C₂₀-alkyl are methyl, ethyl, isopropyl, n-propyl, n-butyl, isobutyl, sec-butyl, tert-butyl, n-hexyl, n-heptyl, n-octyl, 2-ethylhexyl, n-decyl, n-undecyl, n-dodecyl, n-tetradecyl, n-hexadecyl, n-octadecyl and n-eicosyl.

Examples of C₁- to C₄-alkyl are methyl, ethyl, isopropyl, n-propyl, n-butyl, isobutyl, sec-butyl and tert-butyl.

Examples of C₅-C₁₂-cycloalkyl groups are cyclopentyl, cyclohexyl, cycloheptyl, cyclooctyl, cyclononyl, cyclodecyl, cycloundecyl and cyclododecyl; cyclopentyl, cyclohexyl and cycloheptyl are preferred; cyclohexyl is particularly preferred.

C₆-C₁₈-aryl groups are, for example, phenyl, 1-naphthyl, 2-naphthyl, 1-anthryl, 2-anthryl, 9-anthryl, 1-phenanthryl, 2-phenanthryl, 3-phenanthryl, 4-phenanthryl, 9-phenanthryl, terphenyl, preferably phenyl, 1-naphthyl and 2-naphthyl, particularly preferably phenyl.

The radical R is preferably C₁- to C₂₀-alkyl or C₆-C₁₈-aryl, particularly preferably C₁- to C₂₀-alkyl and very particularly preferably C₆- to C₁₂-alkyl.

Preferred radicals R are methyl, ethyl, isopropyl, n-propyl, n-butyl, isobutyl, sec-butyl, tert-butyl, pentyl, hexyl, heptyl, octyl, nonyl, decyl, undecyl, dodecyl and phenyl; methyl, ethyl, n-butyl, isobutyl, tert-butyl, pentyl, hexyl, heptyl, octyl, nonyl, decyl, undecyl, dodecyl and phenyl are particularly preferred; isobutyl, pentyl, hexyl, heptyl, octyl, nonyl, decyl, undecyl, dodecyl and phenyl are very particularly preferred.

Suitable compounds (S) are, for example, isooctyltrimethoxysilane, isooctyltriethoxysilane, n-butyltrimethoxysilane, n-butyltriethoxysilane, isobutyltrimethoxysilane, isobutyltriethoxysilane, phenyltrimethoxysilane and phenyltriethoxysilane.

In a particularly preferred embodiment, R is a partly fluorinated or perfluorinated C₄- to C₂₀-alkyl, preferably C₄- to C₁₈-alkyl and in particular C₈- to C₁₂-alkyl.

If R is a partially fluorinated alkyl, a silane of the general formula (I)

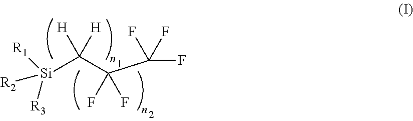

is preferably used. There, R₁, R₂, R₃ independently of one another, are C₁- to C₂₀-alkyl, C₆- to C₁₈-aryl or C₅- to C₁₂-cycloalkyl, methoxy, ethoxy or chlorine, at least one of the radicals R₁, R₂, R₃ being methoxy, ethoxy or chlorine, n₁ is an integer from 0 to 20, preferably from 1 to 4, in particular 2, and n₂ is an integer in the range from 0 to 20, preferably in the range from 4 to 10 and in particular in the range from 6 to 8.

If silanes are used as surface-hydrophobizing substance, they usually bind with at least one of the radicals R₁, R₂, R₃ to the surface of the substrate. The radical R₄ projects away from the substrate and forms the hydrophobic surface.

Suitable silanes which can be used as surface-hydrophobizing substance are, for example, n-octyltrichlorosilane, n-nonyltrichlorosilane, n-decyltrichlorosilane, n-undecyltrichlorosilane, n-dodecyltrichlorosilane, phenyltrichlorosilane, n-octyltriethoxysilane, n-nonyltriethoxysilane, n-decyltriethoxysilane, n-undecyltriethoxysilane, n-dodecyltriethoxysilane, phenyltriethoxysilane, n-octyltrimethoxysilane, n-nonyl-trimethoxysilane, n-decyltrimethoxysilane, n-undecyltrimethoxysilane, n-dodecyltrimethoxysilane, phenyltrimethoxysilane, n-octyldimethylchlorosilane, n-nonyldimethylchlorosilane, n-decyldimethylchlorosilane, n-undecyldimethylchlorosilane, n-dodecyldimethylchlorosilane, phenyldimethylchlorosilan, 1H,1H-perfluoro-octyltrichlorosilane, 1H,1H-perfluorodecyltrichlorosilane, 1H,1H-perfluoro-dodecyltrichlorosilane, 1H,1H-perfluorooctyltriethoxysilane, 1H,1H-perfluorodecyl-triethoxysilane, 1H,1H-perfluorododecyltriethoxysilane, 1H,1H-perfluorooctyltrimethoxysilane, 1H,1H-perfluorodecyltrimethoxysilane, 1H,1H-perfluorododecyltrimethoxysilane, 1H,1H-perfluorooctyldimethylchlorosilane, 1H,1H-perfluorodecyldimethylchlorosilane, 1H,1H-perfluorododecyldimethylchlorosilane, 1H,1H,2H,2H-perfluorooctyltrichlorosilane, 1H,1H,2H,2H-perfluorodecyltrichlorosilane, 1H,1H,2H,2H-perfluorododecyltrichlorosilane, 1H,1H,2H,2H-perfluorooctyltriethoxysilane, 1H,1H,2H,2H-perfluorodecyltriethoxysilane, 1H,1H,2H,2H-perfluorododecyltriethoxysilane, 1H,1H,2H,2H-perfluorooctyltrimethoxysilane, 1H,1H,2H,2H-perfluorodecyltrimethoxysilane, 1H,1H,2H,2H-perfluorododecyltrimethoxysilane, 1H,1H,2H,2H-perfluorooctyldimethylchlorosilane, 1H,1H,2H,2H-perfluorodecyldimethylchlorosilane, 1H,1H,2H,2H-perfluorododecyldimethylchlorosilane.

If the process is used for the production of solar cells, the substrate is usually a wafer comprising a semiconductor material. In general, a material based on silicon is used as semiconductor material. The surface of the wafer to which the structured metallic coating is applied is usually first coated with silicon nitride or passivated. The coating with silicon nitride or the passivation is also carried out in the case of currently produced solar cells and is known to the person skilled in the art. The surface-hydrophobizing substance is then applied as a monolayer or oligolayer to the passivated surface or the surface coated with silicon nitride. The grid customary for solar cells and composed of the substance comprising the electrically conductive particles is imprinted on the monolayer or oligolayer of the surface-hydrophobizing substance. As a result of the coating with the surface-hydrophobizing substance, it is possible to imprint narrow tracks of the grid so that the instance of light is only slightly hindered by the imprinted tracks. If a relatively large thickness of the grid tracks is to be achieved, it is possible to imprint the substance comprising the electrically conductive particles in a plurality of layers. By imprinting the substance comprising the electrically conductive particles and then curing the matrix material present in the substance and evaporating the solvent, a structured metallic coating is achieved on the surface. Usually, the substance used for the production of solar cells and comprising the electrically conductive particles comprises from 50 to 90% by weight of electrically conductive particles, preferably from 65 to 85% by weight and in particular from 70 to 80% by weight of electrically conductive particles, from 0 to 20% by weight of matrix material, preferably from 1 to 15% by weight of matrix material, in particular from 3 to 10% by weight of matrix material, and from 0 to 30% by weight of solvent, preferably from 5 to 25% by weight of solvent and in particular from 5 to 20% by weight of solvent. As a result of the addition of the solvent, the viscosity of the substance comprising the electrically conductive particles can be adjusted according to the printing process used.

The printing process suitable for applying the substance comprising the electrically conductive particles is any desired printing process known to a person skilled in the art. Customary printing processes are, for example, screen printing processes, inkjet printing processes, pad printing processes or laser printing processes. The substance comprising the electrically conductive particles is preferably applied by a laser printing process.

In a suitable laser printing process, the substance comprising the electrically conductive particles and intended for imprinting is first applied to a carrier. The application of the substance to the carrier can be effected by any desired method known to a person skilled in the art. Usually, the substance comprising the electrically conductive particles is applied to the carrier with the aid of a transfer roll.

A flexible carrier is preferably used as the ink carrier. In particular, the ink carrier which is coated with the substance to be imprinted and comprising the electrically conductive particles is band-like. Very particularly preferably, the flexible carrier is a film. The thickness of the carrier is preferably in the range from 1 μm to about 500 μm. It is advantageous to design the carrier to have as small a thickness as possible so that the energy introduced by the carrier is not dispersed in the carrier and a crisp printed image is thus produced. For example, polymers transparent for the energy used are suitable as material for the carrier.

The energy which is used to evaporate the ink and to transfer it to the substrate to be printed on is preferably a laser. An advantage of a laser is that the laser beam used can be focused onto a very small cross section. Thus, targeted energy introduction is possible. In order at least partly to evaporate the substance comprising the electrically conductive particles from the carrier and also to apply it to the substrate, it is necessary to convert the light of the laser into heat. For this purpose, for example, it is possible for the substance comprising the electrically conductive particles furthermore to comprise a suitable absorber which absorbs the laser light and converts it into heat. Alternatively, however, it is also possible to coat the carrier to which the substance comprising the electrically conductive particles is applied with an appropriate absorber or to produce said carrier from such an absorber. It is preferable, however, for the carrier to be produced from a material transparent for the laser radiation and for the absorber which converts the laser light into heat to be present in the substance comprising the electrically conductive particles. For example, carbon black, metal nitrides or metal oxides are suitable as absorbers.

Suitable lasers which may be used in order to introduce energy into the ink are, for example, fiber lasers, which are operated in the base mode.

A further improvement of the printed image is also achieved if the gap between the substrate to be printed on and the carrier on which the substance comprising the electrically conductive particles and intended for printing is applied has a printing gap in the range from 0 to 2 mm, in particular in the range from 0.01 to 1 mm. The smaller the printing gap between the carrier and the substrate to be printed on, the smaller the extent to which the drop diverges on striking the substrate to be printed on and the more uniform the printed image remains. However, it should also be ensured that the substrate to be printed on does not touch the carrier coated with the substance comprising the electrically conductive particles, so that the substance comprising the electrically conductive particles is not transferred at undesired points onto the substrate to be printed on.

In addition to the production of solar cells, the process according to the invention is also suitable, for example, for the production of any desired other electronic components, for example for the production of circuit boards. If circuit boards are produced by the process according to the invention, the substrate used is usually a dielectric as a suitable circuit board substrate. Customary circuit board substrates are, for example, produced from reinforced or unreinforced polymers. Suitable polymers are, for example, bi- and polyfunctional bisphenol A and F-based epoxy resins, epoxy novolak resins, brominated epoxy resins, cycloaliphatic epoxy resins, bismaleimide-triazine resins, polyimides, phenol resins, cyanate esters, melamine resins or amino resins, phenoxy resins, allylated polyphenylene ethers, polysulfones, polyamides, silicone and fluorine resins and combinations thereof.

In order to apply a crisp structure without running edges to the circuit board substrate, the circuit board substrate is first coated, according to the invention, with a monolayer of a surface-hydrophobizing substance. The silanes described above are also preferably used as a surface-hydrophobizing substance in the production of circuit boards.

In the production of circuit boards, the electrically conductive particles may also be carbon particles, for example in the form of nanotubes, in addition to the abovementioned metals.

With the aid of the process according to the invention, any desired electronic components, in particular solar cells or circuit boards, can be produced. An electronic component produced by the process according to the invention comprises in general a substrate to which a structured electrically conductive surface is applied, a monolayer of the surface-hydrophobizing material being applied to the substrate and the structured electrically conductive surface being applied to the monolayer.

If the electronic component is a solar cell, the substrate is generally a wafer comprising a semiconductor material, in particular a silicon-comprising semiconductor material. If the electronic component is a circuit board, the substrate is a circuit board substrate.

### EXAMPLE

200 μl of 1H,1H,2H,2H-perfluorooctyltriethoxysilane are initially taken in a vacuum desiccator. Preprocessed polycrystalline silicon wafers coated with silicon nitride are then introduced into the vacuum desiccator. The vacuum desiccator is closed and a dynamic oil pump vacuum is applied for 3 min. Thereafter, the wafer surface is brought into contact with the 1H,1H,2H,2H-perfluorooctyltriethoxysilane via the gas phase over a period of 12 h in the static vacuum. The 1H,1H,2H,2H-perfluorooctyltriethoxysilane forms an effective surface passivation, the wetting behavior changes and the surface energy, measured according to Owens and Wendt, is reduced by about 40.1 mN/m to about 12.6 mN/m.

1. A process for producing a structured electrically conductive coating, the process comprising:
(a) applying a monolayer or oligolayer of a surface-hydrophobizing substance to a surface of a wafer comprising a semiconductor material, and
(b) imprinting a substance comprising electrically conductive particles according to a predetermined pattern on the wafer.

2. The process of claim 1, wherein the applying (a) is by vapor depositing, spraying on, or immersing.

3. The process of claim 1, wherein the surface-hydrophobizing substance is a silane of the general formula SiR₁R₂R₃R₄ where R₁, R₂ and R₃, are each independently selected from the group consisting of C₁- to C₂₀-alkyl, C₆- to C₁₈-aryl, C₅- to C₁₂-cycloalkyl, methoxy, ethoxy, and chlorine, wherein at least one of R₁, R₂ or R₃ is methoxy, ethoxy or chlorine, and wherein R₄ is C₁- to C₂₀-alkyl that is optionally partly fluorinated or perfluorinated.

4. The process of claim 1, wherein the wafer comprises a silicon nitride coating, an aluminum oxide coating or a silicon carbide coating.

5. The process of claim 1, wherein the substance comprising electrically conductive particles comprises 50 to 90% by weight of electrically conductive particles, 0 to 20% by weight of a matrix material and 0 to 30% by weight of a solvent.

6. The process of claim 1, wherein the electrically conductive particles comprise at least one selected from the group consisting of silver, copper, iron and tin.

7. A solar cell obtained by a process comprising:
applying a monolayer or oligolayer of a surface-hydrophobizing substance to a wafer comprising a semiconductor material, and
(b) applying a structured electrically conductive coating to the monolayer or oligolayer.

8. The process of claim 3, wherein R₁, R₂ and R₃ are each independently selected from the group consisting of ethoxy, methoxy and chlorine.

9. The process of claim 1, wherein the applying (a) is by vapor depositing performed at a pressure of 100 mbar (abs) to 10⁻⁶ mbar (abs).

10. The process of claim 1, wherein the applying (a) is by vapor depositing performed at a temperature of 10 to 100 degrees C.

11. The process of claim 3, wherein R₄ is C₆- to C₁₂-alkyl.

12. The process of claim 3, wherein R₄ is selected from the group consisting of isobutyl, pentyl, hexyl, heptyl, octyl, nonyl, decyl, undecyl, dodecyl.

13. The process of claim 3, wherein R₄ is C₁- to C₂₀-alkyl that is partly fluorinated or perfluorinated.

14. The process of claim 1, wherein the surface-hydrophobizing substance is selected from the group consisting of isooctyltrimethoxysilane, isooctyltriethoxysilane, n-butyltrimethoxysilane, n-butyltriethoxysilane, isobutyltrimethoxysilane, isobutyltriethoxysilane, phenyltrimethoxysilane and phenyltriethoxysilane.

15. The process of claim 1, wherein the surface-hydrophobizing substance is 1H,1H,2H,2H-perfluorooctyltriethoxysilane.

16. The process of claim 1, wherein the substance comprising electrically conductive particles comprises 70 to 80% by weight of electrically conductive particles, 1 to 15% by weight of a matrix material, and 5 to 20% by weight of a solvent.

17. The process of claim 1 wherein the particles comprise silver.

18. The process of claim 1, wherein the particles have a size not more than 10 microns.

19. The process of claim 1, comprising
(a) applying a monolayer of a surface-hydrophobizing substance to a surface of a wafer comprising a semiconductor material.

20. The process of claim 1, comprising
(a) applying an oligolayer of a surface-hydrophobizing substance to a surface of a wafer comprising a semiconductor material.
